(19) United States
(12) Patent Application Publication
(10) Pub. No.: US 2011/0109856 A1
(43) Pub. Date: May 12, 2011

(54) METHOD AND STRUCTURE FOR ELECTRO-PLATING ALUMINUM SPECIES FOR TOP METAL FORMATION OF LIQUID CRYSTAL ON SILICON DISPLAYS

(75) Inventors: HERB HUANG, SHANGHAI (CN); WEI MIN LI, SHANGHAI (CN)

(73) Assignee: SEMICONDUCTOR MANUFACTURING INTERNATIONAL (SHANGHAI) CORPORATION, SHANGHAI (CN)

(21) Appl. No.: 12/938,166

(22) Filed: Nov. 2, 2010

(30) Foreign Application Priority Data
Nov. 11, 2009 (CN) 200910198582.8

(51) Int. Cl. G02F 1/1337; H01L 33/00

(52) U.S. Cl. 349/129; 438/34; 257/88; 257/E33.062

(57) ABSTRACT

Method and structure for electro-plating aluminum species for top metal formation of liquid crystal on silicon displays. In a specific embodiment, the invention provides a method for fabricating a liquid crystal on silicon display device. The method includes providing a substrate, e.g., semiconductor wafer, silicon wafer, silicon on insulator. The method includes forming a transistor layer (e.g., MOS transistors) overlying the substrate. The method includes forming an interlayer dielectric layer (e.g., PSG, BPSG, FSG) overlying the transistor layer. The method includes forming a first conductive layer overlying the interlayer dielectric layer and forming a second interlayer dielectric layer overlying the first conductive layer. A dual damascene via structure is formed within the second interlayer dielectric layer. The method deposits a barrier metal layer (e.g., TiN, Ti/TiN) within the dual damascene via structure to form a liner that covers exposed regions of the dual damascene via structure.

### CROSS-REFERENCES TO RELATED APPLICATIONS

This application claims priority to Chinese Patent Application No. 200910198582.8, filed Nov. 11, 2009, entitled “A Method and Structure of Manufacturing Liquid Crystal on Silicon Devices,” by inventors Herb Huang and Wei Min Li, commonly assigned, and incorporated by reference herein for all purposes.

### BACKGROUND OF THE INVENTION

Embodiments of the present invention are directed to integrated circuits and the processing for the manufacture of electronic devices. More particularly, embodiments of the invention provides a method of manufacturing an electrode structure in a liquid crystal on silicon (“LCOS”) device for displays. But it would be recognized that embodiments of the invention have a much broader range of applicability.

Electronic display technologies have rapidly developed over the years. From the early days, cathode ray tube (CRT) technology scan images repetitively onto a glass screen in conventional television sets. These television sets originally display black and white moving pictures. Color television sets soon replaced most if not all black and white television sets. Despite recent advances, CRTs are bulky, heavy, relatively fragile, difficult to make larger, take up a lot of space, and had other limitations.

CRTs are replaced by flat panel display, with liquid crystal panel displays being the most common flat screen technology. These liquid crystal panel displays, commonly called LCDs, use an array of transistor elements coupled to a liquid crystal material and color filter to display moving pictures in color. Many computer terminals and smaller display devices often relied upon LCDs to output video, text, and other visual features. Unfortunately, liquid crystal panels often have low yields and are difficult to scale up to larger sizes. These LCDs are often unsuitable for larger displays often required for television sets and the like.

Accordingly, projection display units have been developed. These projection display units include, among others, a counterpart liquid crystal display, which outputs light from selected pixel elements through a lens to a larger display to create moving pictures, text, and other visual images. Another technology is called “Digital Light Processing” (DLP), which is a commercial name from Texas Instruments Incorporated (TI) of Texas, USA. DLP is often referred to as the use of “micro-mirrors.” DLP relies upon tiny mirrors to project images. The tiny mirrors are laid out in a matrix on a semiconductor chip. The number of mirrors corresponds to the resolution of the projected image, e.g., 800×600, 1024×768, 1280×720, and 1920×1080 (HDTV) matrices are some common resolutions. Each of the mirrors is hinged. An actuator is attached to each of the hinges. The actuator is often electrostatic energy that can tilt each of the mirrors at high frequency. The moving mirrors can modulate light, which can be transmitted through a lens and then displayed on a screen. Although DLP has been successful, it is often difficult to manufacture and subject to low yields, etc.

Yet another technique is called LCOS, which uses both mirrors and liquid crystals. LCOS uses liquid crystals applied to a reflective mirror substrate. As the liquid crystals “open” or “close,” light is reflected or blocked, which modulates the light to create an image for display. Often times, there are at least three LCOS chips, each corresponding to light in red, green, and blue channels. LCOS, however, has many limitations. As merely an example, LCOS is often difficult to manufacture. Additionally, LCOS requires at least the three chips that make the projector bulky and heavy and leads to high costs. Accordingly, LCOS has not been adapted to portable projectors.

From the above, it is seen that an improved technique for processing devices is desired.

### BRIEF SUMMARY OF THE INVENTION

According to embodiments of the present invention, techniques for processing integrated circuits for the manufacture of electronic devices are provided. More particularly, embodiments of the invention provide a method for manufacturing an electrode structure for a liquid crystal on silicon (“LCOS”) device for displays. But it would be recognized that embodiments of the invention have a much broader range of applicability.

In a specific embodiment, the invention provides a method of fabricating a liquid crystal on silicon display device. The method includes providing a substrate, e.g., semiconductor wafer, silicon wafer, silicon on insulator. The method includes forming a transistor layer (e.g., MOS transistors) overlying the substrate. The method includes forming an interlayer dielectric layer (e.g., PSG, BPSG, FSG) overlying the transistor layer. The method includes forming a first conductive layer overlying the interlayer dielectric layer and forming a second interlayer dielectric layer overlying the first conductive layer. A dual damascene via structure is formed within the second interlayer dielectric layer. The method deposits a barrier metal layer (e.g., TiN, Ti/TiN) within the dual damascene via structure to form a liner that covers exposed regions of the dual damascene via structure. Next, the method electro-plates aluminum material onto the liner to fill the via structure with the aluminum material. Preferably, electro-plating occurs at lower temperatures ranges. The method includes a step of polishing the aluminum material using a chemical mechanical planarization process to form at least a portion of a pixel element from a portion of the aluminum material.

In an alternative specific embodiment, the invention includes an LCOS device. The device has a semiconductor substrate and an MOS device layer overlying the semiconductor substrate. The MOS device layer has a plurality of MOS devices. A planarized interlayer dielectric layer is overlying the MOS device layer. A plurality of dual damascene via structures are within the planarized interlayer dielectric layer. Each of the dual damascene via structures has a via region within a first portion of the planarized interlayer dielectric layer. The via region has a first width and first depth and a surface region within a second portion of the planarized interlayer dielectric layer. The surface region has a second width. The surface region is coupled to the via region. A plated aluminum metal layer fills each of the dual damascene via structures including the via region and surface region for each of the dual damascene via structures to form respective plurality of electrode regions corresponding to each of the recessed regions. Each of the electrode regions is respectively coupled to at least one of the MOS devices among the plurality of MOS devices.

Many benefits are achieved by way of the present invention over conventional techniques. For example, the present technique provides an easy to use process that relies upon conventional technology. In some embodiments, the method provides higher device yields in dies per wafer. Additionally, the method provides a process that is compatible with conventional process technology without substantial modifications to conventional equipment and processes. Preferably, the invention provides for an improved mirror or electrode structure for LCOS devices used for displays. Such electrode structure uses electrode plating techniques that can be maintained at lower temperatures and has good gap filling characteristics. Depending upon the embodiment, one or more of these benefits may be achieved. These and other benefits will be described in more throughout the present specification and more particularly below.

Various additional embodiments, features and advantages of the present invention can be more fully appreciated with reference to the detailed description and accompanying drawings that follow.

### BRIEF DESCRIPTION OF THE DRAWINGS

FIG. 1 is a simplified cross-sectional view diagram of an LCOS device according to an embodiment of the present invention.

FIGS. 2 through 4 illustrate a method for forming an LCOS device according to an embodiment of the present invention

### DETAILED DESCRIPTION OF THE INVENTION

According to the present invention, techniques for processing integrated circuits for the manufacture of electronic devices are provided. More particularly, the invention provides a method of manufacturing an electrode structure in a liquid crystal on silicon (“LCOS”) device for displays. But it would be recognized that the invention has a much broader range of applicability.

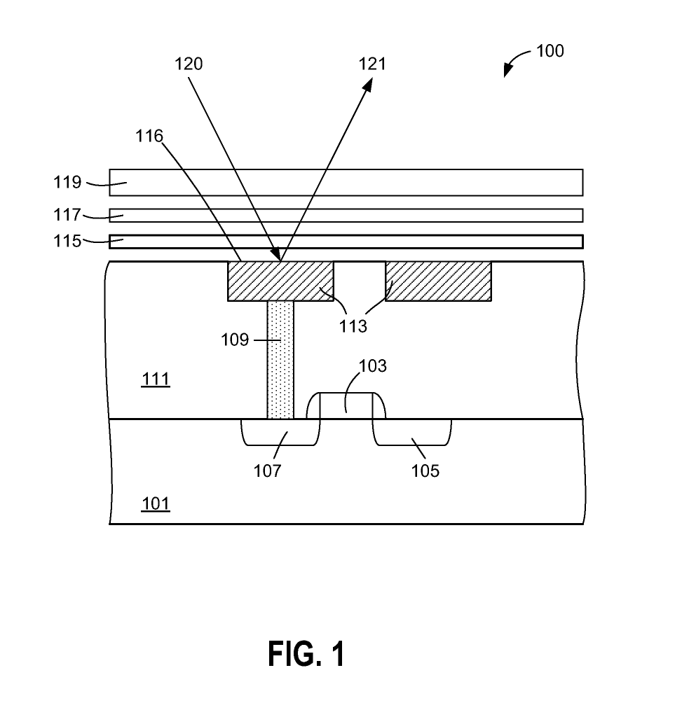

FIG. 1 is a simplified cross-sectional view diagram of an LCOS device 100 according to an embodiment of the present invention. This diagram is merely an example, which should not unduly limit the scope of the claims herein. One of ordinary skill in the art would recognize many variations, alternatives, and modifications. As shown, the LCOS device 100 has a semiconductor substrate 101, e.g., silicon wafer. An MOS device layer 103 is formed overlying the semiconductor substrate. Preferably, the MOS device layer has a plurality of MOS devices. Each of the MOS devices has a contact region 107 for an electrode and a contact region 105 for a voltage potential. A planarized interlayer dielectric layer 111 is formed overlying the MOS device layer. The LCOS device also has a plurality of recessed regions (e.g., damascene structures) within a portion of the interlayer dielectric layer and a metal layer (e.g., aluminum) to fill each of the recessed regions to form respective plurality of electrode regions 113 corresponding to each of the recessed regions. Preferably, the metal layer has been plated into each of the damascene structures. Each of the electrode regions is respectively coupled to at least one of the MOS devices among the plurality of MOS devices via interconnect structure 109, which may be a plug or other like structure. A protective layer is formed overlying surface regions of each of the plurality of electrode regions to protect the surface regions. A mirror finish 116 is on each of the surface regions. Preferably, the mirror finish is substantially free from dishes and scratches from a chemical mechanical polishing process. Each of the electrodes may have a thickness ranging from about 2000 Angstroms to about 4000 Angstroms and can be at other dimensions. Each of the electrodes represents a pixel element in an array of pixel elements for the LCOS device. In an embodiment, each of the pixel elements is characterized by a size of about eight by eight microns in dimension. Also shown are liquid crystal film 115 overlying the electrodes. The LCOS device also has a transparent electrode layer (e.g., indium tin oxide) 117 and an overlying glass plate 119 to enclose the multilayered structure. Details on ways of operating the LCOS device can be found throughout the present specification and more particularly below.

To operate the LCOS device, light 120 traverses through the glass cover, through the transparent electrode, and to the liquid crystal film. When the electrode is not biased, the liquid crystal film is essentially in the off position, which does not allow the light to pass therethrough. Rather, light is blocked and does not reflect off of the mirror surface of the electrode. When the electrode is biased via MOS device, the liquid crystal film is in an on-position, which allows light to pass 121. The light reflects off of the surface of the electrode and through the liquid crystal film, which is in an on-position. Preferably, the mirror surface is substantially free from imperfections. Accordingly, at least 93% of the incoming light passes out 121 of the LCOS device. Details on ways of fabricating the LCOS device can be found throughout the present specification and more particularly below.

A method for fabricating an electrode structure for an LCOS device according to an embodiment of the present invention may be outlined as follows:
1. Provide a substrate;
2. Form a layer of transistor elements overlying the substrate;
3. Form an interlayer dielectric layer overlying the layer of transistor elements;
4. Form a mask overlying the interlayer dielectric layer;
5. Pattern the interlayer dielectric layer to form a plurality of recessed regions for the damascene structures within the interlayer dielectric layer;
6. Form a liner material within exposed regions of the recessed regions;
7. Electro-plate an aluminum layer using an aluminum fill material overlying the recessed region and exposed portions of the interlayer dielectric layer to fill each of the recessed regions;
8. Remove portions of the aluminum layer from the interlayer dielectric layer while the aluminum layer in the recessed regions remain intact;
9. Form a protective layer overlying surface regions of the aluminum layer remaining in the recessed regions;
10. Provide a liquid crystal layer overlying the protective layer, a transparent electrode layer overlying the liquid crystal layer, and a glass layer overlying the transparent electrode layer to form the LCOS device; and
11. Perform other steps, as desired.

The above sequence of steps provides a method according to an embodiment of the present invention. As shown, the method uses a combination of steps including a way of forming an electrode structure using a damascene structure for an LCOS device. Other alternatives can also be provided where steps are added, one or more steps are removed, or one or more steps are provided in a different sequence without departing from the scope of the claims herein. Further details of the present method can be found throughout the present specification and more particularly below.

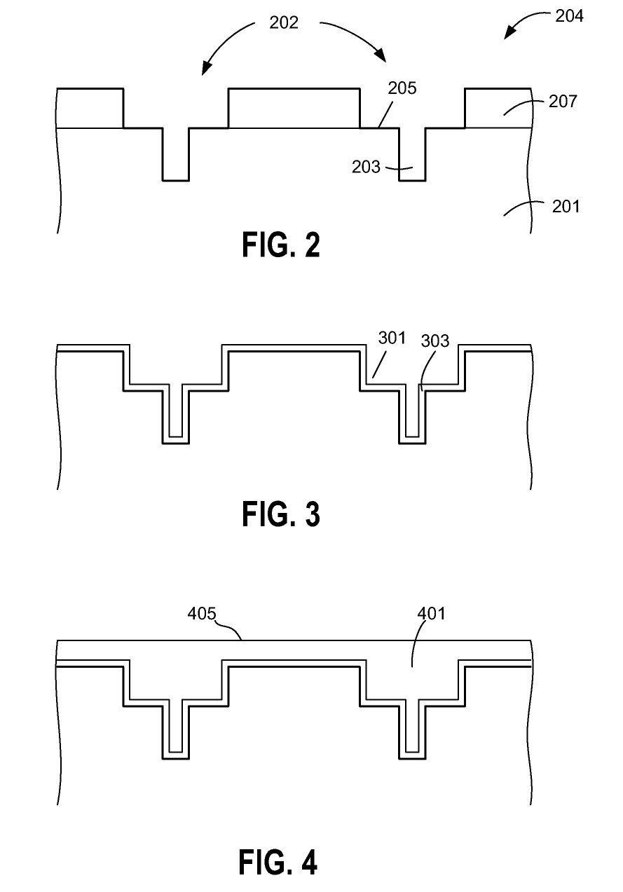

FIGS. 2 through 4 illustrate a method for forming an LCOS device according to an embodiment of the present invention. These diagrams are merely examples, which should not unduly limit the scope of the claims herein. One of ordinary skill in the art would recognize many variations, alternatives, and modifications. These figures focus on forming electrode regions for the pixel electrodes. Referring to FIG. 2 for illustrative purposes, the method begins by providing a semiconductor substrate, e.g., silicon wafer. The method includes forming a transistor layer overlying the substrate. Preferably, the transistor layer has a plurality of MOS devices, each of which includes a first contact region and a second contact region. The method also includes forming an interlayer dielectric layer 201 overlying the transistor layer. The dielectric layer can be made of BPSG, FSG, oxide, any combination of these, and the like. Preferably, the dielectric layer is formed using a chemical vapor deposition process. The method then planarizes the interlayer dielectric layer to form a planarized surface region. Optionally, the dielectric layer has already been planarized.

Referring again to FIG. 2, the method includes patterning a plurality of recessed regions 202 within a portion 204 of the interlayer dielectric layer. The recessed region has a sufficient depth, e.g., ranging from 2000 Angstroms to 4000 Angstroms and less. Each of the recessed regions will correspond to an electrode, which will correspond to a pixel element. Preferably, each of the recessed regions includes via region 203 and surface region 205. The via region connects or couples to an underlying metal layer (not shown). The surface region will correspond to an electrode for the pixel element. In a specific embodiment, the via region is provided in a first portion 201 of the interlayer dielectric layer and the surface region is provided in a second portion 207 of the interlayer dielectric layer. The first portion can correspond to a first layer and the second portion can correspond to a second layer, although the same layer can also be used according to certain embodiments. The recessed region is formed within interlayer dielectric material 207 and 201. In an embodiment, the first interlayer dielectric layer comprises BPSG. In another embodiment, the second interlayer dielectric layer comprises a doped silicon glass. Of course, there can be other variations, modifications, and alternatives.

Referring to FIG. 3, the method includes forming a liner layer 303 within exposed portions 301 of the recessed regions. The liner layer can be formed from a variety of materials. The liner layer can be sputtered. Here, the liner layer can be a barrier metal layer such as titanium nitride, titanium/titanium nitride, and the like. The liner material acts as a barrier and can also assist in adhesion for overlying materials. Depending upon application liner material and thickness thereof may vary.

The method includes forming a metal layer (e.g., aluminum) 401 to fill the recessed regions as illustrated by FIG. 4. The metal layer such as aluminum is plated. Preferably, the aluminum is plated using an electro-chemical process. The plated material has improved gap filling characteristics. The plated material fills up the recessed region and is free from dishing, key holes, etc. In a specific embodiment, the electro-chemical process is used. Of course, there can be other variations, modifications, and alternatives.

As shown, the metal layer has a surface that is substantially planar and has almost no surface defects that influence reflectivity. Each of the electrode regions is respectively coupled to each of the MOS devices among the plurality of MOS devices. Optionally, the method includes a CMP buffing and/or scrubbing step applied to surface 405 to remove any residual aluminum bearing particles and the like. The method also includes forming a protective layer overlying surface regions of each of the plurality of electrode regions 401 to protect the surface regions having a mirror finish for each of the electrode regions. Preferably, at least 93% of the light is reflected back from the mirror finish in completed LCOS devices. The protective layer can be formed by treating the surface of the bare aluminum layer with an oxidizing fluid such as hydrogen peroxide, ozone/water mixtures, and the like. The oxidizing fluid is substantially clean and forms a passivation layer overlying the bare aluminum layer. Depending upon the embodiment, there can be other variations, modifications, and alternatives.

To complete the LCOS device, the method forms a sandwiched layer having liquid crystal materials. Here, a liquid crystal film is formed overlying the electrodes. A transparent electrode structure is formed overlying the liquid crystal film. The method forms a glass plate overlying the transparent electrode. The sandwiched structure is often formed as an assembly, which is later disposed onto surfaces of the electrodes of the LCOS devices. Of course, one of ordinary skill in the art would recognize many variations, alternatives, and modifications.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for fabricating a liquid crystal on silicon display device, the method comprising:
providing a substrate;
forming a transistor layer overlying the substrate;
forming an interlayer dielectric layer overlying the transistor layer;
forming a first conductive layer overlying the interlayer dielectric layer;
forming a second interlayer dielectric layer overlying the first conductive layer;
forming a dual damascene via structure within the second interlayer dielectric layer;
depositing a barrier metal layer within the dual damascene via structure to form a liner that covers exposed regions of the dual damascene via structure;
electro-plating an aluminum layer onto the liner to fill the via structure with an aluminum material, the via structure being coupled to at least one transistor in the transistor layer through the first conductive layer; and
polishing the aluminum layer using a chemical mechanical planarization process to form at least a portion of a pixel element from a portion of the aluminum material.

2. The method of claim 1, wherein the second interlayer dielectric layer comprises a doped silicon glass.

3. The method of claim 1, wherein the portion of the pixel element is one of a plurality of pixel elements for the liquid crystal on silicon display device.

4. The method of claim 1, wherein the barrier metal layer comprises titanium nitride.

5. The method of claim 1, wherein the first interlayer dielectric layer comprises BPSG.

6. The method of claim 1, wherein a surface region of the aluminum layer is free from dishing or scratching from the chemical mechanical planarization process.

7. The method of claim 1, wherein the aluminum material is characterized by a reflectivity of 93% and greater.

8. The method of claim 1, wherein the portion of the pixel element is coupled to an MOS device.

9. The method of claim 8, wherein the MOS device is adapted to apply voltage to the portion of the pixel element and acts as an electrode.

10. The method of claim 9, wherein the portion of the pixel element is characterized by a size of about eight by eight microns in dimension.

11. The method of claim 1, wherein the pixel element comprises a thickness ranging from about 2000 Angstroms to about 4000 Angstroms.

12. A liquid crystal on silicon (LCOS) device, the device comprising:
a semiconductor substrate;
an MOS device layer overlying the semiconductor substrate, the MOS device layer having a plurality of MOS devices;
a planarized interlayer dielectric layer overlying the MOS device layer;
a plurality of dual damascene via structures within the planarized interlayer dielectric layer, each of the dual damascene via structures comprising:
a via region within a first portion of the planarized interlayer dielectric layer, the via region having a first width and a first depth;
a surface region within a second portion of the planarized interlayer dielectric layer, the surface region having a second width, the surface region being coupled to the via region;
a plated aluminum metal layer to fill each of the dual damascene via structures including the via region and surface region for each of the dual damascene via structures to form respective plurality of electrode regions corresponding to each of the recessed regions, each of the electrode regions being respectively coupled to at least one of the MOS devices among the plurality of MOS devices.

13. The device of claim 12, wherein each of the electrode regions corresponds to a pixel element.

14. The device of claim 12, wherein the planarized interlayer dielectric layer comprising the first portion and the second portion.

15. The device of claim 12, wherein the planarized interlayer dielectric layer comprises BPSG.

16. The device of claim 12 further comprising a liner layer on and in contact with exposed regions of the plurality of dual damascene via structures.

17. The device of claim 12 further comprising a protective layer overlying the plated aluminum metal layer.

18. The device of claim 17 further comprising a liquid crystal material overlying the protective layer.
